(19) United States
(12) Patent Application Publication
(10) Pub. No.: US 2026/0130216 A1
(43) Pub. Date: May 7, 2026

(54) SEMICONDUCTOR DEVICE AND METHOD FOR FABRICATING SAME

(71) Applicant: WUHAN XINXIN SEMICONDUCTOR MANUFACTURING CO., LTD., 430205 (CN)

(72) Inventors: Hang YAN, Wuhan (CN); Beibei SHENG, Wuhan (CN); Sheng HU, Wuhan (CN)

(21) Appl. No.: 19/371,560

(22) Filed: Oct. 28, 2025

(30) Foreign Application Priority Data
Nov. 4, 2024 (CN) 202411563659.8

(51) Int. Cl. H01L 23/373; H01L 21/74; H01L 21/78; H01L 23/00; H01L 23/48; H01L 25/18; H10B 80/00; H10D 80/30

(52) U.S. Cl. CPC H10W 40/258; H10B 80/00; H10D 80/30; H10P 54/00; H10W 20/021; H10W 20/20; H10W 90/00; H10W 80/312; H10W 80/327; H10W 90/792

(57) ABSTRACT

A semiconductor device and a method for fabricating it are disclosed. In the method, second and first substrates are bonded to obtain increased operating efficiency. Moreover, a heat dissipation unit, which includes a heat-dissipating semiconductor layer and a first heat-dissipating metal channel extending through the heat-dissipating semiconductor layer and dielectric layers on a surface thereof, is bonded to a surface of the first substrate to accelerate dissipation of heat generated during operation of the second and first substrates, imparting improved heat dissipation capacities to the semiconductor device.

### CROSS-REFERENCE TO RELATED APPLICATION

This application claims the priority of Chinese patent application number 202411563659.8, filed on Nov. 4, 2024, and entitled “SEMICONDUCTOR DEVICE AND METHOD FOR FABRICATING SAME”, the entire contents of which are incorporated herein by reference.

### TECHNICAL FIELD

The present invention relates to the field of semiconductor technology and, in particular, to a semiconductor device and a method for fabricating it.

### BACKGROUND

Data processing power (or computing power) of semiconductor chips has made important contribution to the booming of artificial intelligence (AI), big data and related techniques. As these techniques continue to develop rapidly, increasingly demanding requirements are being placed on the computing power of related semiconductor chips.

Vertically interconnecting multiple dies can result in a higher level of integration, a shorter global wiring length, accelerated interconnection speed, faster response and lower energy consumption. For example, a substrate with large storage capacity may be obtained by vertically interconnecting multiple dies and then packaged with a data processing substrate into a 3D integrated device (such as a chip). With this arrangement, due to physical proximity between the two substrates, data can be processed more efficiently with less transfer delays and reduced power consumption.

However, the increasing level of integration of such 3D integrated devices brings about more significant heat generation during operation, making heat dissipation one of the core problems that adversely impact their performance.

### SUMMARY OF THE INVENTION

The present invention provides a 3D integrated semiconductor device with high operating efficiency and improved heat dissipation capabilities and a method for fabricating such a device.

In one aspect, the present invention provides a semiconductor device comprising:
a first substrate and at least one second substrate bonded to the first substrate; and
a heat dissipation unit bonded to a surface of the first substrate, the heat dissipation unit comprising: a heat-dissipating semiconductor layer; at least one dielectric layer stacked on at least one surface of the heat-dissipating semiconductor layer; and a first heat-dissipating metal channel extending through the heat-dissipating semiconductor layer and the at least one dielectric layer in a thickness direction.

Optionally, the first substrate may be a silicon interposer, or a data processing substrate, and the at least one second substrate may be a memory unit with a stacked structure.

Optionally, at least one second substrate may comprise a second heat-dissipating metal channel extending therethrough along a thickness thereof.

Optionally, the first substrate may comprise two opposite surfaces, wherein the second substrate and the heat dissipation unit are spaced apart and both bonded to a same surface of the first substrate, or wherein the second substrate and the heat dissipation unit are bonded to the two surfaces.

Optionally, the first substrate may further comprise:
a bond material layer bonded to the second substrate and the heat dissipation unit; and
at least one heat-dissipating metal structure disposed in the bond material layer.

Optionally, the heat-dissipating metal structure may comprise a heat-dissipating metal layer formed in the bond material layer, a heat-dissipating bond pad embedded in a surface of the bond material layer and a heat-dissipating plug connecting the heat-dissipating metal layer and the heat-dissipating bond pad.

Optionally, the first heat-dissipating metal channel may be connected to the heat-dissipating metal structure.

Optionally, the semiconductor device may further comprise:
an encapsulation layer, which covers the second substrate, the heat dissipation unit and the first substrate and fills any gap therebetween; and
a heat-conducting layer and a heat-dissipating metal sheet, which are sequentially stacked on a surface of the encapsulation layer.

In another aspect, the present invention provides a method for fabricating a semiconductor device, which comprises:
dicing a heat-conducting substrate formed from a semiconductor substrate to obtain at least one heat dissipation unit, wherein the heat dissipation unit comprises: a heat-dissipating semiconductor layer made up of the semiconductor substrate; at least one dielectric layer stacked on at least one surface of the heat-dissipating semiconductor layer; and a first heat-dissipating metal channel extending through the semiconductor substrate layer and the at least one dielectric layer in a thickness direction; and
bonding and interconnecting at least one second substrate with a first substrate and bonding at least one heat dissipation unit to a surface of the first substrate.

Optionally, the formation of the heat-conducting substrate may comprise:
forming a first dielectric layer on the semiconductor substrate and forming a first heat-dissipating metal layer on a surface of the first dielectric layer;
forming a second dielectric layer covering the first dielectric layer and the first heat-dissipating metal layer, forming at least one first through hole extending through the second dielectric layer and exposing the first heat-dissipating metal layer and forming at least one first bond pad opening by widening an upper portion of the first through hole;
filling a metal material in the first through hole and the first bond pad opening to form a first heat-dissipating plug and a first heat-dissipating bond pad;
bonding a first carrier to a side of the second dielectric layer away from the semiconductor substrate and thinning the semiconductor substrate from a side thereof away from the first carrier;
forming a third dielectric layer on the thinned surface of the semiconductor substrate and forming at least one second through hole extending through the third dielectric layer, the semiconductor substrate and the first dielectric layer and exposing the first heat-dissipating metal layer; and
filling a metal material in the second through hole to form a second heat-dissipating plug, wherein the second heat-dissipating plug, the first heat-dissipating metal layer, the first heat-dissipating plug and the first heat-dissipating bond pad constitute the first heat-dissipating metal channel.

The at least one second substrate may comprise a stacked structure, wherein formation of the second substrate with the stacked structure comprises: stacking and interconnecting at least two base substrates to obtain a 3D substrate stack; and dicing the 3D substrate stack.

Optionally, the formation of the 3D substrate stack may comprise:
providing a first base substrate comprising a front side and an opposite backside;
forming a fourth dielectric layer on the front side of the first substrate and forming, in the fourth dielectric layer, first redistribution layer, at least one first interconnect bond pad and at least one first via connecting the first redistribution layer and the first interconnect bond pad;
bonding a second carrier to the fourth dielectric layer and thinning the first base substrate from the backside;
forming a fifth dielectric layer on the thinned backside of the first base substrate and forming at least one second via extending through the fifth dielectric layer, the first substrate and the fourth dielectric layer and connected to the first redistribution layer;
forming a sixth dielectric layer on the fifth dielectric layer and forming, in the sixth dielectric layer, a second redistribution layer, at least one second interconnect bond pad and at least one third via connecting the second redistribution layer and the second interconnect bond pad; and
bonding and connecting the first base substrate to the second substrate.

Optionally, the formation of the 3D substrate stack may further comprise:
during the formation of the first redistribution layer, the first interconnect bond pad and the first via, forming, in the fourth dielectric layer, a second heat-dissipating metal layer, at least one second heat-dissipating bond pad and at least one third heat-dissipating plug connecting the second heat-dissipating metal layer and the second heat-dissipating bond pad;
during the formation of the second via connected to the first redistribution layer, forming at least one fourth heat-dissipating plug extending through the fifth dielectric layer, the first substrate and the fourth dielectric layer and connected to the second heat-dissipating metal layer; and
during the formation of the second redistribution layer, the second interconnect bond pad and the third via, forming, in the sixth dielectric layer, a third heat-dissipating metal layer, at least one third heat-dissipating bond pad and at least one fifth heat-dissipating plug connecting the third heat-dissipating metal layer and the third heat-dissipating bond pad,
wherein the second heat-dissipating metal layer, the second heat-dissipating bond pad, the third heat-dissipating plug, the fourth heat-dissipating plug, the third heat-dissipating metal layer, the third heat-dissipating bond pad and the fifth heat-dissipating plug constitute a second heat-dissipating metal channel.

Optionally, the method may further comprise, before bonding and interconnecting the first base substrate to the second base substrate,
forming a bond material layer on a surface of the first substrate, at which the bonding is to be conducted, and forming at least one heat-dissipating metal structure in the bond material layer.

In the semiconductor device and method for fabricating the device of the present invention, the second and first substrates are bonded, resulting in increased operating efficiency (e.g., data processing efficiency). In addition, a heat dissipation unit, which includes a heat-dissipating semiconductor layer and a first heat-dissipating metal channel extending through the heat-dissipating semiconductor layer and at least one dielectric layer on a surface thereof, is bonded to a surface of the first substrate to accelerate dissipation of heat generated during operation of the second and first substrates, imparting improved heat dissipation capacities to the semiconductor device.

### BRIEF DESCRIPTION OF THE DRAWINGS

FIG. 1 shows a schematic flowchart of a method for fabricating a semiconductor device according to an embodiment of the present invention.

FIGS. 2 to 8 are schematic cross-sectional views showing the formation of a heat dissipation unit in a method for fabricating a semiconductor device according to another embodiment of the present invention.

FIGS. 9 to 15 are schematic cross-sectional views showing the formation of a second substrate with a stacked structure in a method for fabricating a semiconductor device according to an embodiment of the present invention.

FIGS. 16 to 18 are schematic cross-sectional views showing the bonding of second substrate(s) and heat dissipation unit(s) to a first substrate in a method for fabricating a semiconductor device according to an embodiment of the present invention.

### DETAILED DESCRIPTION

Semiconductor devices and methods of fabrication thereof according to specific embodiments of the present invention will be described in greater detail below with reference to the accompanying drawings. From the following description, advantages and features of the present invention will become more apparent. Note that the figures are provided in a very simplified form not necessarily drawn to exact scale for the only purpose of helping to explain the embodiments disclosed herein in a more convenient and clearer way. Also note that the order of steps in the method as presented herein is not the only order in which these steps must be performed. Rather, some of the steps may be omitted, and/or other steps that are not described herein may be added. It will be understood that, as used herein, spatially relative terms are intended to encompass different orientations of the device in use or operation in addition to the orientation depicted in the figures. For example, if the device in the figures is inverted or otherwise oriented (e.g., rotated), the exemplary term “over” can encompass an orientation of “under” and other orientations.

In order to speed up the dissipation of heat generated by a chip during its operation, it is a typical practice to form a heat-conducting layer on a surface of the chip and a heat-dissipating metal sheet (or heat sink) covering the heat-conducting layer and dissipating heat by heat exchange between the heat-dissipating metal sheet and the air. However, for a 3D integrated chip at a high level of integration, which generates much heat when processing massive data at a high speed, it would be difficult for the generated heat to be transferred to the heat-dissipating metal sheet as quickly as desired. Therefore, heat tends to build up within the chip, and affects the chip's normal operation. Embodiments of the present invention relates to a semiconductor device and a method for fabricating it, in which first and second substrates are integrated to provide high operating efficiency, and they are additionally integrated with at least one heat dissipation unit, which enhances heat dissipation and imparts improved heat dissipation properties. Description of the method is set forth below first.

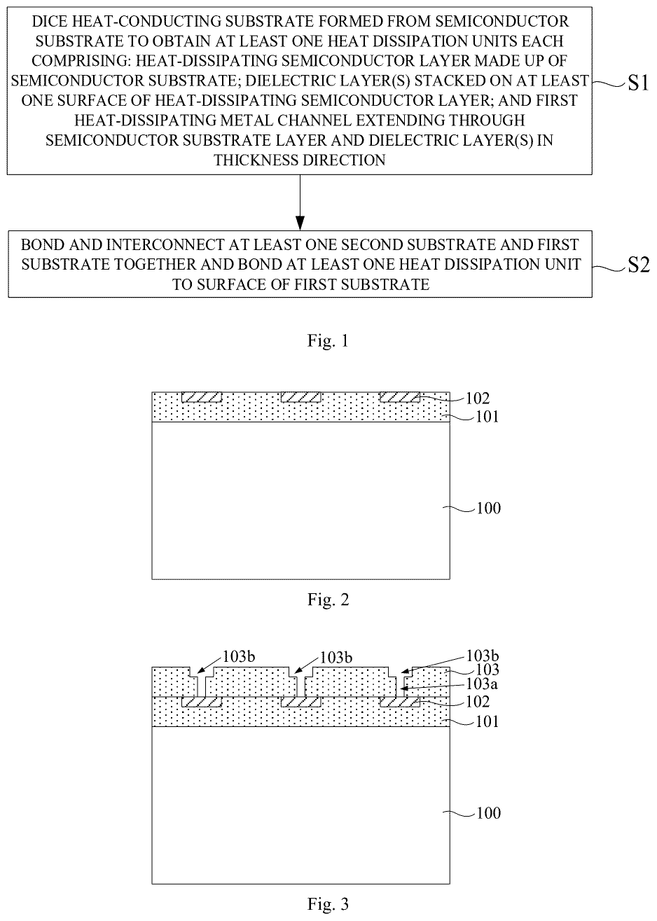

Referring to FIG. 1, according to an embodiment of the present invention for fabricating a semiconductor device, in step S1 of the method, a heat-conducting substrate based on a semiconductor substrate is diced to obtain individual heat dissipation units each including a heat-dissipating semiconductor layer made up of the semiconductor substrate, dielectric layer(s) stacked on at least one surface of the heat-dissipating semiconductor layer and first heat-dissipating metal channel(s) extending through the semiconductor substrate layer and the dielectric layer(s) in a thickness direction.

According to embodiments of the present invention, in step S1 of the method, a heat dissipation unit is formed in the semiconductor device, which includes a heat-dissipating semiconductor layer made up of a semiconductor substrate and a dielectric layer to be subsequently bonded to a first substrate. Depending on desired heat dissipation capacities of the semiconductor device, heat dissipation performance of a heat-conducting substrate based on the semiconductor substrate may be appropriately adjusted. For example, the semiconductor substrate may be a silicon substrate with good thermal conductivity (the thermal conductivity of silicon is about 140 W/(m·K) at room temperature). However, the present invention is so limited, as the semiconductor substrate may also be implemented as a different substrate with good thermal conductivity, such as a silicon-germanium substrate, a silicon carbide substrate, or the like.

In addition to the heat-dissipating semiconductor layer made up of a semiconductor substrate, the heat dissipation unit formed in step S1 also includes heat-dissipating metal channels, which impact even better heat-conducting properties. For example, step S1 may particularly include the processes as detailed below.

Referring to FIG. 2, a first dielectric layer 101 is formed on a semiconductor substrate 100, and a first heat-dissipating metal layer 102 is formed on the first dielectric layer 101. For example, the first heat-dissipating metal layer 102 may be copper or another metal material. For example, recesses may be formed in a surface of the first dielectric layer 101 by performing a damascene process thereon, and a metal material may be filled in the recesses, forming the first heat-dissipating metal layer 102 embedded in the surface of the first dielectric layer 101.

Referring to FIG. 3, forming a second dielectric layer 103 which covers the first dielectric layer 101 and the first heat-dissipating metal layer 102, and forming first through holes 103a which extend through the second dielectric layer 103 and expose the first heat-dissipating metal layer 102. An upper portion of the first through hole 103a is widened to form first bond pad opening 103b on the top of the first through hole 103a. The first through hole 103a and/or the first bond pad opening 103b may also be formed otherwise.

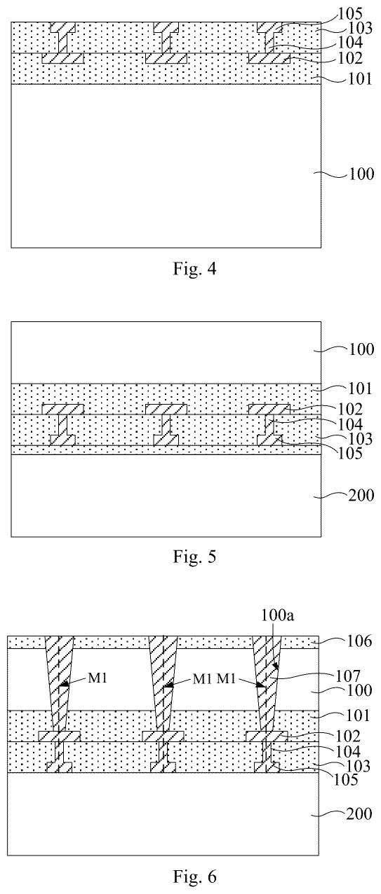

Referring to FIG. 4, a metal material is filled in the first through holes 103a and the first bond pad openings 103b, forming first heat-dissipating plugs 104 in the first through hole 103a and first heat-dissipating bond pads 105 in the first bond pad openings 103b.

Referring to FIG. 5, a first carrier 200 is bonded to a side of the second dielectric layer 103 away from the semiconductor substrate 100, and the semiconductor substrate 100 is thinned from a side thereof away from the first carrier 200. Prior to bonding, a dielectric material may be formed between the second dielectric layer 103 and the first carrier 200.

Referring to FIG. 6, a third dielectric layer 106 is formed on the thinned surface of the semiconductor substrate 100, and second through hole 100a extending through the third dielectric layer 106, the semiconductor substrate 100 and the first dielectric layer 101 and exposing the first heat-dissipating metal layer 102 is formed. A metal material is filled in the second through holes 100a to form second heat-dissipating plugs 107. The second heat-dissipating plug 107, together with the first heat-dissipating metal layer 102, first heat-dissipating plug 104 and the first heat-dissipating bond pad 105 constitutes the first heat-dissipating metal channel M1.

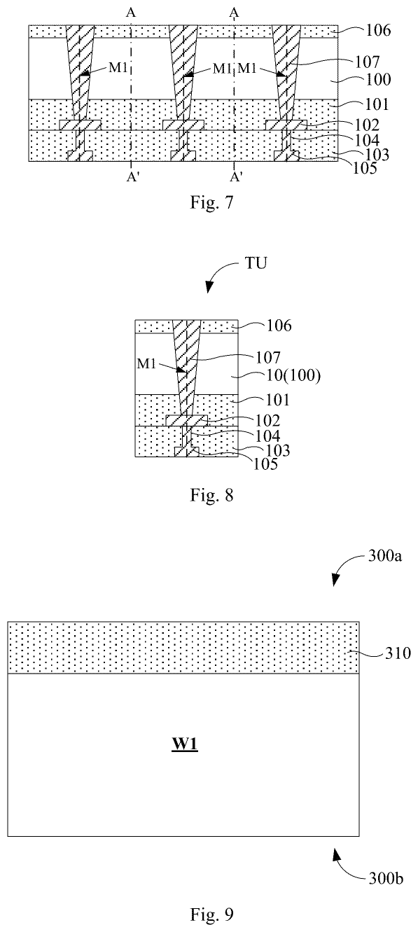

Referring to FIG. 7, the first carrier 200 is removed, and a heat-conducting substrate is obtained.

Referring to FIG. 8, the heat-conducting substrate is diced in a thickness direction thereof (e.g., along lines AA′ of FIG. 7) into individual dies each containing a portion of the semiconductor substrate 100 and at least one of the aforementioned first heat-dissipating metal channels M1. This die is used as heat dissipation unit TU, and its effective heat-dissipating components include a heat-dissipating semiconductor layer 10 made up of the semiconductor substrate 100 and the first heat-dissipating metal channel M1. Because of good thermal conductivity of the metal material (the first heat-dissipating metal channels M1 may be made of copper, the thermal conductivity of which at room temperature is about 385 W/(m·K)), improved heat dissipation can be provided compared with simply relying on the semiconductor substrate for heat dissipation.

A thickness of the heat dissipation unit TU may be controlled through thinning the semiconductor substrate 100 during their fabrication. The thinning of the semiconductor substrate 100 may take into account a height of a space reserved in the semiconductor device being fabricated for a heat dissipation unit. For example, in some embodiments, a heat dissipation unit TU and a second substrate may be subsequently bonded to a single surface of a first substrate. Accordingly, the thinning of the semiconductor substrate 100 may be controlled so that the heat dissipation unit TU has a thickness equal or close to a thickness of the second substrate (e.g., with a difference between the two thicknesses being controlled below a preset value).

Referring to FIG. 1, according to embodiments of the present invention for fabricating a semiconductor device, in step S2 of the method, at least one second substrate is bonded to and interconnected with a first substrate with at least one heat dissipation unit TU being bonded to a surface of the first substrate.

In some embodiments, the first substrate may include at least one of a silicon interposer, a data processing substrate and a memory substrate, and the second substrate may include at least one of a data processing unit (DPU) and a memory unit. The data processing substrate and data processing unit may include a logic die (e.g., central processing unit (CPU), graphics processing unit (GPU), system-on-a-chip (SoC), microcontroller unit (MCU), etc.), and the memory substrate and memory unit may include a dynamic random access memory (DRAM) die, static random access memory (SRAM) die or other die. The first or second substrate may further include a power management (e.g., power management integrated circuit (PMIC)) die, radio frequency (RF) die, sensor die, micro-electro-mechanical-system (MEMS) die, signal processing (e.g., digital signal processing) die, front-end (e.g., analog front-end (AFE)) die or other die, or a combination thereof. Each of the silicon interposer, the data processing substrate, the memory substrate, the DPU and the memory unit may be a stacked structure.

The at least one second substrate that is bonded to and interconnected with the first substrate may each be a stacked structure or single layer (i.e., non-stacked) structure. Depending on desired heat dissipation capacities of the semiconductor device, in some embodiments, the at least one second substrate that is bonded to and interconnected with the first substrate may contain heat-dissipating metal channel extending therethrough, which can impart good heat dissipation properties to the second substrate. In this way, in the resulting semiconductor device, both the second substrate and the heat dissipation unit TU can dissipate heat, resulting in increased heat dissipation efficiency.

The formation of the second substrate) is explained below in the context of it being implemented as a stacked structure, as an example. The second substrate with a stacked structure may be, for example, a stacked memory unit.

The formation of the second substrate with a stacked structure may include: stacking and interconnecting at least two base substrates to form a 3D substrate stack; and dicing the 3D substrate stack. In the following embodiments, depending on desired heat dissipation capacities of the semiconductor device, the formation of the 3D substrate stack may include, in addition to stacking and interconnecting the at least two base substrates, forming heat-dissipating metal channel extending through all the substrates. It will be understood that, depending on desired heat dissipation capacities of the semiconductor device, the formation of the 3D substrate stack may include only stacking and interconnecting the at least two base substrates, but not forming heat-dissipating metal channel.

Referring to FIG. 9, a first base substrate W1 is provided, which has a front side 300a and an opposite backside 300b, and a fourth dielectric layer 310 is formed on the front side 300a. According to embodiments of the present application, the first base substrate W1 may be a wafer or other semiconductor material. The first base substrate W1 may contain memory devices (not shown), such as DRAM and/or SRAM, formed on the front side 300a that is opposite to the backside 300b.

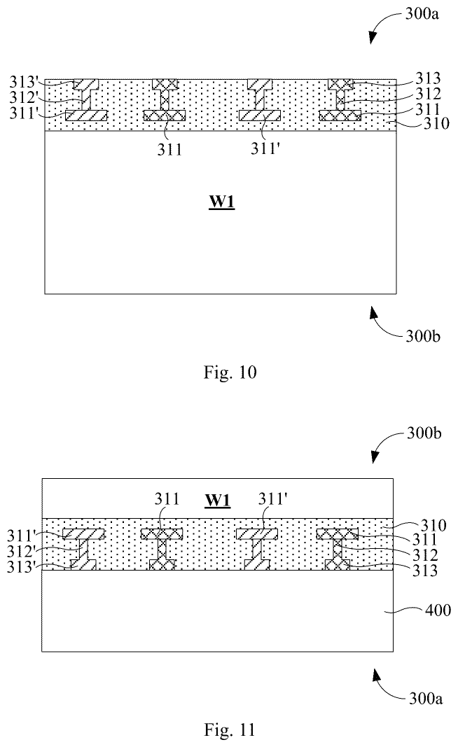

Next, referring to FIG. 10, in the fourth dielectric layer 310 are formed first redistribution layer 311, first interconnect bond pads 313 and first vias 312 connecting the first redistribution layer 311 to the first interconnect bond pads 313. In the illustrated embodiment, in the fourth dielectric layer 310 are further formed second heat-dissipating metal layer 311′, second heat-dissipating bond pads 313′ and third heat-dissipating plugs 312′ connecting the second heat-dissipating metal layer 311′ to the second heat-dissipating bond pads 313′. The first redistribution layer 311, the first interconnect bond pad 313, the first via 312, the second heat-dissipating metal layer 311′, the second heat-dissipating bond pad 313′ and the third heat-dissipating plug 312′ may be formed using the same process as described above for forming the first heat-dissipating metal layer 102, the first heat-dissipating plug 104 and the first heat-dissipating bond pad 105 on the semiconductor substrate 100, and reference can be made to the above description for more details thereof. For example, a dielectric layer is formed, and a damascene process is then performed to form on a surface of the dielectric layer, the first redistribution layer 311 and the second heat-dissipating metal layer 311′ that is insulated and isolated from the first redistribution layer 311. Subsequently, another dielectric layer is formed on said dielectric layer, and then through holes corresponding to the first redistribution layer 311 and the second heat-dissipating metal layer 311′ are formed. An upper portion of each through hole is then widened according to the size of an interconnect bond pad or heat-dissipating bond pad to be formed therein. After that, the through hole is filled with a metal material, forming the first via 312 and the first interconnect bond pad 313 corresponding to the first redistribution layer 311 and forming the third heat-dissipating plug 312′ and the second heat-dissipating bond pad 313′ corresponding to the second heat-dissipating metal layer 311′.

Afterwards, referring to FIG. 11, a second carrier 400 is bonded to the front side 300a of the first base substrate W1, and the first base substrate W1 is thinned from the backside 300b.

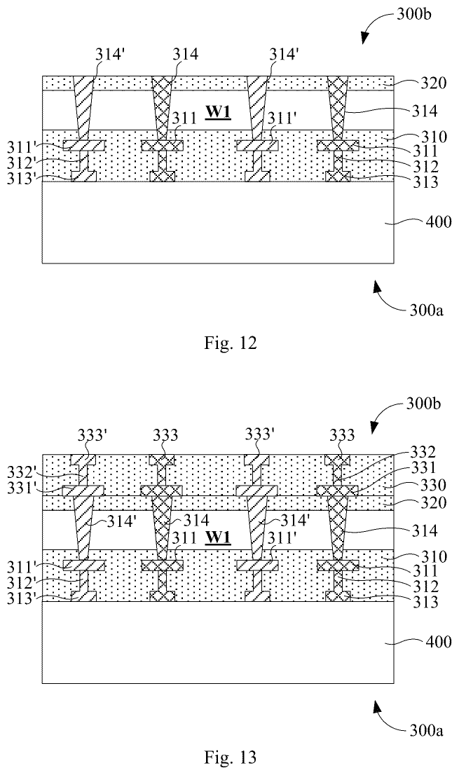

After that, referring to FIG. 12, a fifth dielectric layer 320 is formed on the backside 100b of the first base substrate W1, and the second via 314 extending through the fifth dielectric layer 320, the first base substrate W1 and the fourth dielectric layer 310 and connected to the first redistribution layer 311 is formed. In the illustrated embodiment, the fourth heat-dissipating plug 314′ is also formed, which extends through the fifth dielectric layer 320, the first base substrate W1 and the fourth dielectric layer 310 and is connected to the second heat-dissipating metal layer 311′. The second via 314 and the fourth heat-dissipating plug 314′ may be formed using the same process as described above for forming the second heat-dissipating plug 107 on the thinned side of the semiconductor substrate 100, and reference can be made to the above description for more details thereof.

Next, referring to FIG. 13, a sixth dielectric layer 330 is formed on a surface of the fifth dielectric layer 320, and second redistribution layer 331, second interconnect bond pads 333 and third vias 332 connecting the second redistribution layer 331 to the second interconnect bond pads 333 are formed in the sixth dielectric layer 330. In the illustrated embodiment, in the sixth dielectric layer 330 are also formed third heat-dissipating metal layer 331′, third heat-dissipating bond pads 333′ and fifth heat-dissipating plugs 332′ connecting the third heat-dissipating metal layer 331′ to the third heat-dissipating bond pads 333′.

The first redistribution layer 311, the first via 312, the first interconnect bond pad 313, the second via 314, the second redistribution layer 331, the third via 332 and the second interconnect bond pad 333 constitute a metal interconnect structure extending through the first base substrate W1. This metal interconnect structure may connect the memory device in the first base substrate W1. On the other hand, the second heat-dissipating metal layer 311′, the third heat-dissipating plug 312′, the second heat-dissipating bond pad 313′, the fourth heat-dissipating plug 314′, the third heat-dissipating metal layer 331′, the fifth heat-dissipating plug 332′ and the third heat-dissipating bond pad 333′ constitute a heat-dissipating metal structure extending through the first base substrate W1. The heat-dissipating metal structure provides the heat-dissipating metal channel in the second substrate.

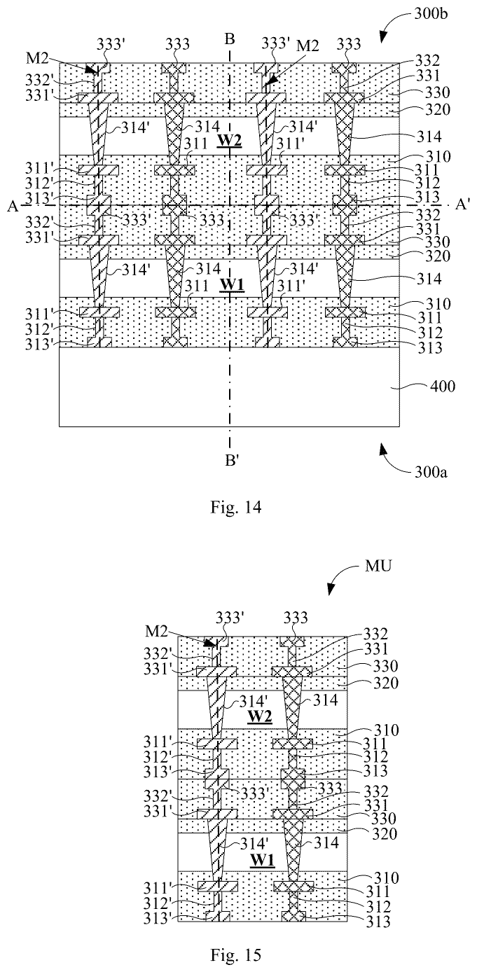

Referring to FIG. 14, the first base substrate W1 is bonded to a second base substrate W2. For example, a front side of the second base substrate W2, on which memory devices are formed, may be oriented to face, and bonded to, the backside 300b of the first base substrate W1 (e.g., along line AA′ of FIG. 14). For example, the second base substrate W2 may also have a front side 300a and an opposite backside 300b. Prior to bonding, the second base substrate W2 may have undergone the same process as described above on the first base substrate W1. Therefore, it may also contain the same metal interconnect structure and heat-dissipating metal structure extending therethrough. For example, the metal interconnect structure may also include first redistribution layer 311, first via 312, first interconnect bond pad 313, second via 314, second redistribution layer 331, third via 332 and second interconnect bond pad 333, and the heat-dissipating metal structure may also include second heat-dissipating metal layer 311′, third heat-dissipating plug 312′, second heat-dissipating bond pad 313′, fourth heat-dissipating plug 314′, third heat-dissipating metal layer 331′, fifth heat-dissipating plug 332′ and third heat-dissipating bond pad 333′.

The metal interconnect structure in the first base substrate W1 is interconnected with the metal interconnect structure in the second base substrate W2 and the heat-dissipating metal structure in the first base substrate W1 is interconnected with heat-dissipating metal structure in the second base substrate W2 by bonding the first base substrate W1 and the second base substrate W2. However, the present invention is not so limited. In another embodiment, some of the metal interconnect structures and some of the heat-dissipating metal structures in the second base substrate W2 may also be formed after it is bonded to the first base substrate W1. According to embodiments of the present application, the bonding may be accomplished using techniques including, but not limited to, hybrid bonding, fusion bonding and bump bonding.

The above described process for forming the metal interconnect structure and heat-dissipating metal structure in the first and second base substrates W1, W2 and bonding the first base substrate W1 to the second base substrate W2 may be repeated to form a 3D substrate stack with a specified number of stacked and interconnected base substrates, in which the metal interconnect structures in the individual base substrates are interconnected, and the heat-dissipating metal structures in the base substrates are interconnected to form heat-dissipating metal channels (referred to hereinafter as the second heat-dissipating metal channel M2). After that, the second carrier 400 may be removed.

For example, the 3D substrate stack may consist of the bonded first and second base substrates W1, W2 as discussed above. After the 3D substrate stack is formed, it is diced in a thickness direction thereof (e.g., along line BB′ of FIG. 14), thus obtaining the aforementioned at least one second substrate with stacked structure, such as memory unit(s) MU as shown in FIG. 15. For example, the memory unit MU may include multiple memory dies, which are formed in respective substrates and stacked together. In each memory unit MU, the dies may be bonded and electrically interconnected by metal interconnect as described above. Additionally, the heat-dissipating metal structure in the dies in each memory unit MU are connected together. Each memory unit MU may include one, two or more second heat-dissipating metal channels M2 as discussed above. Alternatively, it may not include any such heat-dissipating metal channel.

After the at least one second substrate is obtained, it is bonded to and interconnected with the first substrate so that the at least one heat dissipation unit TU as discussed above is bonded to a surface of the first substrate.

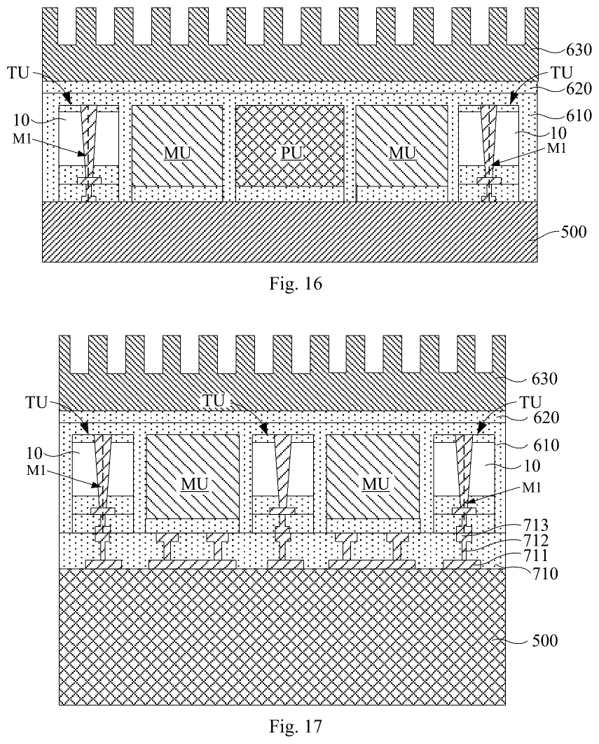

Referring to FIG. 16, in one embodiment, in step S2, the first substrate 500 is a silicon interposer, and the at least one second substrate bonded to the first substrate 500 is a memory unit MU with a stacked structure. Additionally, the at least one second substrate may be a data processing unit PU in the form of a stacked or a non-stacked structure. For example, the data processing unit PU may be a CPU die, a GPU die, a stack of multiple CPU dies formed in respective substrates, or a stack of multiple GPU dies formed in respective substrates.

As shown in FIG. 16, the at least one second substrate (e.g., including memory unit(s) MU and data processing unit(s) PU) and the at least one heat dissipation unit TU are bonded to a surface of the first substrate 500. The second substrate may include heat-dissipating metal channel, or not.

The first substrate 500 may include a substrate, multiple dielectric layers stacked on the substrate and vias and metal layer formed in the dielectric layers. The second substrate is bonded to the first substrate 500 so as to be connected to the first substrate 500. Moreover, in case of multiple second substrates, these second substrates may be interconnected via the first substrate 500. For example, each of the second substrates may include the metal interconnect structure as discussed above, and these metal interconnect structures may be interconnected via the first substrate 500. Further, some of the second substrates may further include the second heat-dissipating metal channel M2 as discussed above. The second heat-dissipating metal channel M2 in the second substrates may be connected to a heat-dissipating component in the first substrate 500 and thereby interconnecting the second heat-dissipating metal channels M2 in the second substrate. In some embodiments, the second heat-dissipating metal channels M2 in the second substrate may be connected to corresponding metal interconnect structure therein, or to corresponding metal interconnect structures in the first substrate 500. The at least one heat dissipation unit TU may be arranged between adjacent second substrates on the first substrate 500 or around the adjacent second substrates. In some embodiments, the heat dissipation unit TU may be connected to an electrically conductive or heat-dissipating component in the first substrate 500 and hence interconnected with the second heat-dissipating metal channel M2 in the second substrate.

As shown in FIG. 16, after the second substrate and the heat dissipation unit TU are bonded to the first substrate 500, on the first substrate 500 may be further formed an encapsulation layer 610, a heat-conducting layer 620 and a heat-dissipating metal sheet 630 (e.g., a heat sink). The encapsulation layer 610 covers the first substrate 500 and the second substrate and the heat dissipation unit TU that are bonded to the first substrate 500 and fills any gap therebetween. The heat-dissipating metal sheet 630 is formed on a side of the encapsulation layer 610 away from the first substrate 500, and the heat-conducting layer 620 is formed between the encapsulation layer 610 and the heat-dissipating metal sheet 630. Furthermore, another substrate (e.g., a PCB or packaging substrate, not shown) may be bonded to a surface of the first substrate 500 facing away from the second substrate. The resulting semiconductor device includes the structure of FIG. 16. In this semiconductor device, the heat dissipation unit TU can quickly transfer heat generated during operation of the second substrate and the first substrate 500 to the heat-conducting layer 620 and the heat-dissipating metal sheet 630.

In the semiconductor device of FIG. 16, the at least one heat dissipation unit TU may be alternatively bonded to the surface of the first substrate 500 away from the second substrate, instead of to the same surface of the first substrate 500 as the second substrate, while still creating an effect of heat transfer. For example, the heat-conducting layer 620 and the heat-dissipating metal sheet 630 may be provided on at least one side of the heat dissipation unit TU.

Referring to FIG. 17, in one embodiment, the first substrate 500 in step S2 is a data processing substrate, which may be implemented as a CPU die, a GPU die, a stack of multiple CPU dies formed in respective base substrates, or a stack of multiple GPU dies formed in respective base substrates. The at least one second substrate bonded to the first substrate 500 is a memory unit MU with a stacked structure. In case of multiple heat dissipation units TU being bonded to the first substrate 500, these heat dissipation units TU may be arranged in gaps between adjacent second substrates or around the second substrate. For example, in FIG. 17, there is no heat-dissipating metal channel in the second substrate.

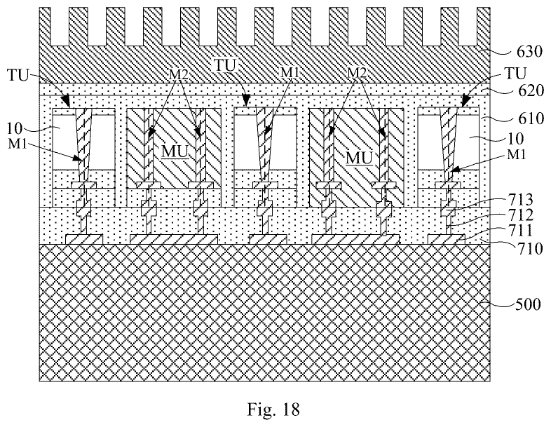

Referring to FIG. 18, in another embodiment, the first substrate 500 in step S2 is a data processing substrate, and the at least one second substrate bonded to the first substrate 500 is a memory unit MU with a stacked structure and contains second heat-dissipating metal channels M2. In this embodiment, heat generated during operation of the second substrate can be quickly transferred through the heat dissipation unit TU, or through the second heat-dissipating metal channel M2. With this arrangement, high heat dissipation efficiency and remarkably improved heat transfer performed can be achieved.

As shown in FIGS. 17 and 18, optionally, before the second substrate(s) and the heat dissipation unit (TU are bonded to and interconnected with the first substrate 500, a seventh dielectric layer 710 may be formed on the surface of the first substrate 500, on which the bonding is to be carried out, and heat-dissipating metal structure(s) may be formed in the seventh dielectric layer 710 to enhance heat dissipation. The heat-dissipating metal structure may include a fourth heat-dissipating metal layer 711 formed in the seventh dielectric layer 710, a fourth heat-dissipating bond pad 713 embedded in a surface of the seventh dielectric layer 710 and a sixth heat-dissipating plug 712 connecting the fourth heat-dissipating metal layer 711 to the fourth heat-dissipating bond pad 713.

In the embodiments of FIGS. 17 and 18, after the second substrate and the heat dissipation unit TU are bonded to the first substrate 500, on the first substrate 500 may be further formed an encapsulation layer 610, a heat-conducting layer 620 and a heat-dissipating metal sheet 630. The encapsulation layer 610 covers the second substrate and the heat dissipation unit and fills any gap therebetween. The heat-dissipating metal sheet 630 is formed on a side of the encapsulation layer 610 away from the first substrate 500, and the heat-conducting layer 620 is formed between the encapsulation layer 610 and the heat-dissipating metal sheet 630. Additionally, another substrate (e.g., a PCB or packaging substrate, not shown) may be bonded to a surface of the first substrate 500 facing away from the second substrate and the heat dissipation unit TU. In the embodiments of FIGS. 16 to 18, at least the heat dissipation unit TU can enhance heat dissipation from the resulting semiconductor device, allowing heat generated by the second substrate and the first substrate 500 to be quickly transferred to the heat-conducting layer 620 and the heat-dissipating metal sheet 630.

In the above method, bonding and interconnecting the second substrate and the first substrate 500 together can result in increased operating efficiency (e.g., data processing efficiency). Moreover, bonding the at least one heat dissipation unit TU to the first substrate 500 can impart improved heat dissipation capacities.

Embodiments of the present invention are also related to a semiconductor device obtainable according to the method for fabricating a semiconductor device discussed above, or according to other suitable methods.

Referring to FIGS. 2 to 18, according to embodiments of the present invention, the semiconductor device includes a first substrate 500, at least one second substrate and a heat dissipation unit TU. The at least one second substrate is bonded to the first substrate 500, and the heat dissipation unit TU is bonded to a surface of the first substrate 500. The heat dissipation unit TU includes: a heat-dissipating semiconductor layer 10; dielectric layers stacked on at least one surface of the heat-dissipating semiconductor layer 10; and first heat-dissipating metal channel M1 extending through the heat-dissipating semiconductor layer 10 and the dielectric layers in a thickness direction.

The first substrate may be a silicon interposer, or a data processing substrate.

The at least one second substrate may comprise a stacked structure. For example, the second substrate may be memory unit MU with a stacked structure including at least two bonded and connected memory dies which are electrically interconnected by a metal interconnect.

As shown in FIGS. 16 and 18, the at least one second substrate may include second heat-dissipating metal channels M2 extending therethrough in a thickness direction thereof and configured for heat dissipation. The first heat-dissipating metal channel M1 and/or the second heat-dissipating metal channel M2 may be connected to electrically conductive component or heat-dissipating component in the first substrate 500. Adjacent first heat-dissipating metal channels M1, adjacent second heat-dissipating metal channels M2, or the first heat-dissipating metal channels M1 and the second heat-dissipating metal channels M2 may be interconnected through the first substrate 500.

As shown in FIGS. 16 to 18, in one embodiment, the first substrate 500 has two opposite surfaces. The second substrate and the heat dissipation unit TU are spaced from each other and bonded to one surface of the first substrate 500, and the first substrate 500 may be bonded to and interconnected with a packaging substrate (not shown) at the other surface. However, the present invention is not so limited. In another embodiment, the second substrate may be bonded to one surface of the first substrate 500, while the heat dissipation unit TU may be bonded to the other surface of the first substrate 500.

As shown in FIGS. 16 to 18, in some embodiments, the first substrate 500 includes a bond material layer (e.g., the seventh dielectric layer 710) and heat-dissipating metal structures formed in the bond material layer. The bond material layer is bonded to the second substrate and the heat dissipation unit TU. For example, the heat-dissipating metal structure may include a fourth heat-dissipating metal layer 711 formed in the bond material layer, a fourth heat-dissipating bond pad 713 embedded in a surface of the bond material layer and a sixth heat-dissipating plug 712 connecting the fourth heat-dissipating metal layer 711 to the fourth heat-dissipating bond pad 713. The fourth heat-dissipating bond pad 713 may be bonded and connected to the heat-dissipating metal channel in the second substrate or heat dissipation unit. However, the present invention is not so limited. For example, in another embodiment, the heat-dissipating metal structure in the bond material layer may include only the fourth heat-dissipating metal layer 711. The first heat-dissipating metal channel M1 and/or the second heat-dissipating metal channel M2 may be connected to the heat-dissipating metal structure in the first substrate 500.

As shown in FIGS. 16 to 18, the semiconductor device may further include an encapsulation layer 610, a heat-dissipating metal sheet 630 and a heat-conducting layer 620. The encapsulation layer 610 covers the second substrate(s), the first substrate 500 and the heat dissipation unit TU and fills any gap therebetween. The heat-conducting layer 620 and the heat-dissipating metal sheet 630 are sequentially stacked on a surface of the encapsulation layer 610.

In this semiconductor device, bonding and interconnecting the second substrate and the first substrate 500 together can result in increased operating efficiency. Moreover, the heat dissipation unit TU that is bonded to the first substrate 500 and includes a heat-dissipating semiconductor layer 10 and a first heat-dissipating metal channel M1 extending through the heat-dissipating semiconductor layer 10 and dielectric layers on surface(s) thereof can accelerate dissipation of heat generated during operation of the second substrate and the first substrate 500, imparting improved heat dissipation capacities to the semiconductor device.

It is noted that the embodiments disclosed herein are described in a progressive manner, with the description of each embodiment focusing on its differences from others. Cross-reference can be made between the embodiments for their common features.

While the invention has been described above with reference to several preferred embodiments, it is not intended to be limited to these embodiments in any way. In light of the teachings hereinabove, any person of skill in the art may make various possible variations and changes to the disclosed embodiments without departing from the scope of the invention. Accordingly, any and all such simple variations, equivalent alternatives and modifications made to the foregoing embodiments without departing from the scope of the invention are intended to fall within the scope thereof.

What is claimed is:

1. A semiconductor device, comprising:
a first substrate and at least one second substrate bonded to the first substrate; and
a heat dissipation unit bonded to a surface of the first substrate, wherein the heat dissipation unit comprises: a heat-dissipating semiconductor layer; at least one dielectric layer stacked on at least one surface of the heat-dissipating semiconductor layer; and a first heat-dissipating metal channel extending through the heat-dissipating semiconductor layer and the at least one dielectric layer in a thickness direction.

2. The semiconductor device of claim 1, wherein the first substrate is a silicon interposer, or a data processing substrate, and at least one second substrate is a memory unit with a stacked structure.

3. The semiconductor device of claim 1, wherein at least one second substrate comprises a second heat-dissipating metal channel extending therethrough along a thickness thereof.

4. The semiconductor device of claim 1, wherein the first substrate comprises two opposite surfaces, wherein the second substrate and the heat dissipation unit are spaced apart and bonded to a same surface of the first substrate, or wherein the second substrate and the heat dissipation unit are bonded to the two surfaces of the first substrate.

5. The semiconductor device of claim 4, wherein the first substrate further comprises:
a bond material layer bonded to the second substrate and the heat dissipation unit; and
at least one heat-dissipating metal structure disposed in the bond material layer.

6. The semiconductor device of claim 5, wherein the heat-dissipating metal structure comprises a heat-dissipating metal layer formed in the bond material layer, a heat-dissipating bond pad embedded in a surface of the bond material layer and a heat-dissipating plug connecting the heat-dissipating metal layer and the heat-dissipating bond pad.

7. The semiconductor device of claim 5, wherein the first heat-dissipating metal channel is connected to the heat-dissipating metal structure.

8. The semiconductor device of claim 1, further comprising:
an encapsulation layer, that covers the second substrate, the heat dissipation unit and the first substrate and fills gaps therebetween; and
a heat-conducting layer and a heat-dissipating metal sheet, sequentially stacked on a surface of the encapsulation layer.

9. A method for fabricating a semiconductor device, comprising:
dicing a heat-conducting substrate formed from a semiconductor substrate to obtain at least one heat dissipation unit, wherein the heat dissipation unit comprises: a heat-dissipating semiconductor layer made up of the semiconductor substrate; at least one dielectric layer stacked on at least one surface of the heat-dissipating semiconductor layer; and a first heat-dissipating metal channel extending through the semiconductor substrate layer and the at least one dielectric layer in a thickness direction;
bonding and interconnecting at least one second substrate with a first substrate; and
bonding at least one heat dissipation unit to a surface of the first substrate.

10. The method of claim 9, wherein the formation of the heat-conducting substrate comprises:
forming a first dielectric layer on the semiconductor substrate,
forming a first heat-dissipating metal layer on a surface of the first dielectric layer,
forming a second dielectric layer covering the first dielectric layer and the first heat-dissipating metal layer,
forming at least one first through hole extending through the second dielectric layer and exposing the first heat-dissipating metal layer,
forming at least one first bond pad opening by widening an upper portion of the first through hole;
filling a metal material in the first through hole and the first bond pad opening to form a first heat-dissipating plug and a first heat-dissipating bond pad,
bonding a first carrier to a side of the second dielectric layer away from the semiconductor substrate and thinning the semiconductor substrate from a side thereof away from the first carrier;
forming a third dielectric layer on the thinned surface of the semiconductor substrate,
forming at least one second through hole that extends through the third dielectric layer, the semiconductor substrate and the first dielectric layer and exposes the first heat-dissipating metal layer; and
filling a metal material in the second through hole to form a second heat-dissipating plug, wherein the second heat-dissipating plug, the first heat-dissipating metal layer, the first heat-dissipating plug and the first heat-dissipating bond pad constitute the first heat-dissipating metal channel.

11. The method of claim 9, wherein at least one second substrates comprise a stacked structure, wherein formation of the second substrate with the stacked structure comprises: stacking and interconnecting at least two base substrates to obtain a three-dimensional (3D) substrate stack; and dicing the 3D substrate stack.

12. The method of claim 11, wherein the formation of the 3D substrate stack comprises:
providing a first base substrate comprising a front side and an opposite backside;
forming a fourth dielectric layer on the front side of the first substrate,
in the fourth dielectric layer, forming a first redistribution layer, at least one first interconnect bond pad and at least one first via connecting the first redistribution layer and the first interconnect bond pad;
bonding a second carrier to the fourth dielectric layer and thinning the first base substrate from the backside;
forming a fifth dielectric layer on the thinned backside of the first base substrate,
forming at least one second via extending through the fifth dielectric layer, the first base substrate and the fourth dielectric layer and connected to the first redistribution layer;
forming a sixth dielectric layer on the fifth dielectric layer,
forming, in the sixth dielectric layer, a second redistribution layer, at least one second interconnect bond pad and at least one third via connecting the second redistribution layer and the second interconnect bond pad; and
bonding and connecting the first base substrate to the second base substrate.

13. The method of claim 12, wherein the formation of the 3D substrate stack further comprises:
during the formation of the first redistribution layer, the first interconnect bond pad and the first via, forming, in the fourth dielectric layer, a second heat-dissipating metal layer, at least one second heat-dissipating bond pad and at least one third heat-dissipating plug connecting the second heat-dissipating metal layer and the second heat-dissipating bond pad;
during the formation of the second via connected to the first redistribution layer, forming at least one fourth heat-dissipating plug extending through the fifth dielectric layer, the first substrate and the fourth dielectric layer and connected to the second heat-dissipating metal layer; and
during the formation of the second redistribution layer, the second interconnect bond pad and the third via, forming, in the sixth dielectric layer, a third heat-dissipating metal layer, at least one third heat-dissipating bond pad and at least one fifth heat-dissipating plug connecting the third heat-dissipating metal layer and the third heat-dissipating bond pad,
wherein the second heat-dissipating metal layer, the second heat-dissipating bond pad, the third heat-dissipating plug, the fourth heat-dissipating plug, the third heat-dissipating metal layer, the third heat-dissipating bond pad and the fifth heat-dissipating plug constitute a second heat-dissipating metal channel.

14. The method of claim 9, further comprising, before bonding and interconnecting the first base substrate to the second base substrate,
forming a bond material layer on a surface of the first substrate, at which the bonding is to be conducted, and
forming at least one heat-dissipating metal structure in the bond material layer.
